(19) United States
(12) Patent Application Publication
(10) Pub. No.: US 2025/0063737 A1
(43) Pub. Date: Feb. 20, 2025

(54) ELECTRONIC DEVICES INCLUDING CAPACITORS, AND RELATED METHODS

(71) Applicant: Micron Technology, Inc., Boise, ID (US)

(72) Inventors: Beth R. Cook, Boise, ID (US); Zhuo Chen, Boise, ID (US); Yixin Yan, Boise, ID (US); Sarah P. Sredzinski, Meridian, ID (US); Gloria Y. Yang, Boise, ID (US); Kathryn H. Russo, Boise, ID (US)

(21) Appl. No.: 18/753,940

(22) Filed: Jun. 25, 2024

Related U.S. Application Data
(60) Provisional application No. 63/520,038, filed on Aug. 16, 2023.

(51) Int. Cl. H10B 53/30

(52) U.S. Cl. CPC H10B 53/30

(57) ABSTRACT

An electronic device comprises a memory array comprising access lines, data lines, and memory cells. Each memory cell is coupled to an associated access line and an associated data line and each memory cell comprises an access device, and a capacitor adjacent to the access device. The capacitor comprises a first electrode, a second electrode separated from the first electrode by an insulative material, and a leaker device adjacent to the first electrode. The second electrode and the leaker device extend through a lattice insulative material adjacent to the first electrode. The leaker device exhibits a substantially circular cross-sectional shape in a direction that is transverse to a direction in which the leaker device extends, with portions of the leaker device extending within a recessed region of the insulative material. Methods of forming electronic devices are also disclosed.

### CROSS-REFERENCE TO RELATED APPLICATION

This application claims the benefit under 35 U.S.C. § 119(e) of U.S. Provisional Patent Application Ser. No. 63/520,038, filed Aug. 16, 2023, the disclosure of which is hereby incorporated herein in its entirety by this reference.

### TECHNICAL FIELD

Embodiments disclosed herein relate to the field of electronic device design and fabrication. More particularly, embodiments of the disclosure relate to electronic devices including capacitors including leaker devices, and related methods of forming electronic devices.

### BACKGROUND

A continuing goal of integrated circuit fabrication is to increase integration density. Memory devices may include, for example, random-access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory). A memory device may be volatile or non-volatile. Non-volatile memory (e.g., flash memory) may store data for extended periods of time even in the absence of an external power source. Volatile memory (e.g., DRAM) may lose stored data over time unless the volatile memory is refreshed by a power source.

DRAM utilizes capacitors (e.g., DRAM capacitors) to store an amount of electrical charge that represents the logical value of a stored bit. Some capacitors include container-shaped capacitors having one electrode shaped as a container, with a cell dielectric material and another electrode on the inside of the container only (e.g., a single-sided hole capacitor), or on the outside of the container only (e.g., a single-sided pillar capacitor), or on both the inside and outside of the container (e.g., a double-sided container capacitor). To increase integration density, the lateral footprint of the capacitors has been reduced by increasing the aspect ratio (i.e., ratio of height to width (e.g., diameter)) and decreasing the proximity of adjacent capacitors to one another. The high aspect ratio and smaller dimensions have led to structurally weak container capacitors that are prone to toppling or breaking. The container-shaped capacitors have a hollow, cylindrical shape stabilized at the top and bottom but are capable of lateral movement, which causes deformation of (e.g., damage to) the capacitor. Therefore, the structural stability and mechanical strength of the container (e.g., the bottom electrode) is significant to the operability of the capacitor in a DRAM device.

FeRAM may use similar device architectures as volatile memory but may have non-volatile properties due to the use of a ferroelectric capacitor as a storage device. For example, FeRAM may include faster write speeds and endurance for repeated memory access with lower power consumption than other types of non-volatile memory. FeRAM may provide non-volatile functionality comparable to that of flash memory with a speed and architecture comparable to that of DRAM.

Titanium nitride (TiN) has been used as an electrode material in capacitors due to its good step coverage and interfacial properties with the cell dielectric material of the memory device. The TiN also exhibits good mechanical, chemical inertness, and electrical resistance (e.g., low resistance) properties. With the decreasing size of the capacitors, TiN bottom electrodes of the capacitors have decreased in thickness. However, the reduced thickness of the TiN bottom electrode impacts the surface area of the capacitors and increases the susceptibility of the TiN to problems associated with oxidation. As the thickness of the TIN decreases, the resistance (Rs) increases exponentially, limiting the use of TiN as an electrode material in smaller capacitors. The TiN bottom electrodes also provide support and mechanical strength during the fabrication of the capacitors. With the decreasing size of the capacitors, retaining structures (e.g., lattice structures) have been used to strengthen the TiN bottom electrode, by supporting exterior side surfaces of the containers defined by the TiN bottom electrodes. However, using the retaining structures increases the complexity of the capacitor fabrication process.

In some instances, so-called “leakage” and “parasitic currents” between adjacent capacitors may be the result of degradation of a leaker device material (e.g., a conductive material) of leaker devices during use and operation of the memory device and/or during formation thereof. For example, removing (e.g., etching) portions of the leaker device material during process acts to remove (e.g., etch) portions of the retaining structures and surrounding materials to form openings (e.g., lattice openings of the retaining structures) may result in defects within (e.g., at the interface of) the leaker device material and subsequently formed conductive materials (e.g., conductive electrodes) of the capacitors.

### BRIEF DESCRIPTION OF THE SEVERAL VIEWS OF THE DRAWINGS

FIGS. 1A through 6B are simplified, partial top-down views (FIGS. 1A, 2A, 3A, 4A, 5A, and 6A) and simplified, partial cross-sectional views (FIGS. 1B, 2B, 3B, 4B, 5B, and 6B) illustrating a method of forming an electronic device according to embodiments of the disclosure;

FIG. 7 is a simplified, partial top-down view of a conventional electronic device at a similar processing stage as that of FIG. 6A;

FIG. 8 is a functional block diagram of an electronic device in accordance with embodiments of the disclosure; and

FIG. 9 is a schematic block diagram of an electronic system in accordance with embodiments of the disclosure.

### DETAILED DESCRIPTION

An electronic device (e.g., a microelectronic device, a semiconductor device, a memory device) is disclosed that includes a memory array including access lines (e.g., word lines), data lines (e.g., digit lines, bit lines), and memory cells (e.g., ferroelectric memory cells). Each memory cell is coupled (e.g., electrically coupled) to an associated access line and an associated data line and each memory cell includes an access device (e.g., a transistor), and a capacitor adjacent to the access device. The capacitor includes a first electrode (e.g., a bottom electrode), a second electrode (e.g., a top electrode) separated from the first electrode by an insulative material (e.g., cell insulative material), and a leaker device adjacent to (e.g., overlying) the first electrode. The second electrode and the leaker device extend through a lattice insulative material (e.g., of a retaining structure) adjacent to (e.g., overlying) the first electrode. The leaker device exhibits a substantially circular cross-sectional shape in a direction that is transverse to a direction (e.g., the X-direction, the Y-direction) in which the leaker device extends, with portions of the leaker device extending within a recessed region of the cell insulative material of the capacitor.

In some embodiments, an electronic device may be formed by forming a lattice insulative material over a first sacrificial material overlying conductive contacts, removing portions of the lattice insulative material to form first openings (e.g., lattice openings) and to expose the first sacrificial material, and removing additional portions of the lattice insulative material and portions of the first sacrificial material to form second openings (e.g., pillar openings, stud openings) and to expose the conductive contacts. A first electrode material (e.g., of first electrodes) may be formed within the second openings. An insulative material (e.g., the cell insulative material) may be formed adjacent to the first electrode material. The method may include forming a second sacrificial material within the first openings, and forming leaker devices over the first electrode material. The second sacrificial material may be removed and a second electrode material (e.g., of second electrodes) may be formed adjacent to the insulative material in locations vacated by the removal of the second sacrificial material to form capacitors. Forming the first openings may include patterning the lattice insulative material prior to forming the first electrode material and the leaker devices.

By patterning the lattice insulative material prior to forming the first electrode material and the leaker devices, damage to surrounding materials (e.g., the leaker devices, the insulative material) may be reduced or substantially eliminated. Further, forming the second sacrificial material adjacent to the insulative material, such as within central regions of the second openings, may further reduce damage to the surrounding materials and/or improve structural support during formation of the capacitors. By reducing damage to the surrounding materials and/or improving structural support, the electronic device according to embodiments of the disclosure may exhibit improved electrical properties and reduced leakage between adjacent capacitors compared to capacitors of conventional electronic devices.

The following description provides specific details, such as material types, material thicknesses, and process conditions in order to provide a thorough description of embodiments described herein. However, a person of ordinary skill in the art would understand that the embodiments of the disclosure may be practiced without employing these specific details. Indeed, the embodiments of the disclosure may be practiced in conjunction with conventional apparatus fabrication techniques employed in the industry. In addition, the description provided below does not form a complete process flow for manufacturing an apparatus (e.g., an electronic device, a microelectronic device, a memory device, such as DRAM memory device, FeRAM memory device). The structures described below do not form a complete apparatus. Only those process acts and structures necessary to understand the embodiments of the disclosure are described in detail below. Additional acts to form a complete apparatus from the structures may be performed by conventional fabrication techniques.

Drawings presented herein are for illustrative purposes only, and are not meant to be actual views of any particular material, component, structure, electronic device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 108.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

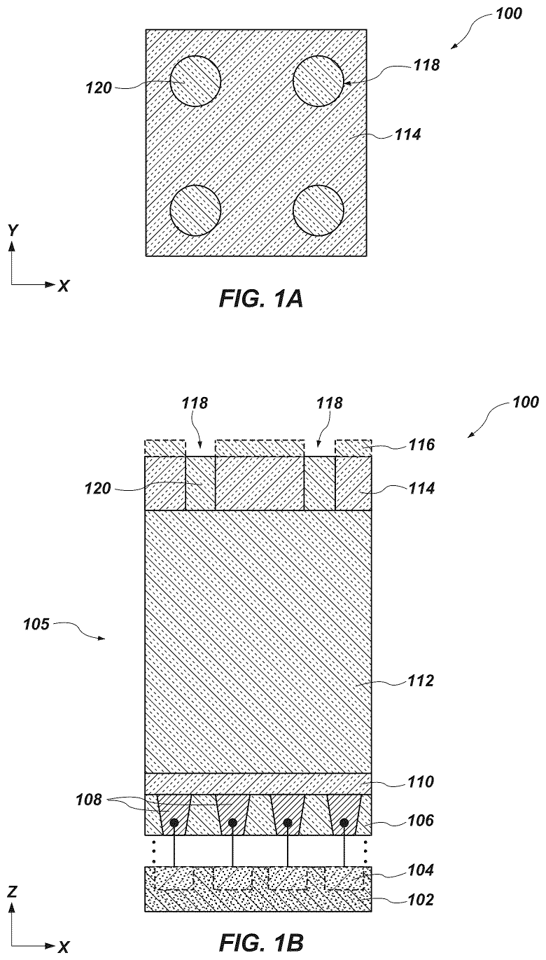

FIGS. 1A through 6B illustrate a method of forming an electronic device (e.g., a microelectronic device, a memory device, a DRAM memory device, a FeRAM memory device), in accordance with embodiments of the disclosure. FIG. 1A is a simplified, partial top-down view of an electronic device 100. FIG. 1B is a simplified, partial cross-sectional view of the electronic device 100 at the processing stage of FIG. 1A. The electronic device 100 may, for example, be formed into a portion of a memory device including capacitors, as described in further detail below.

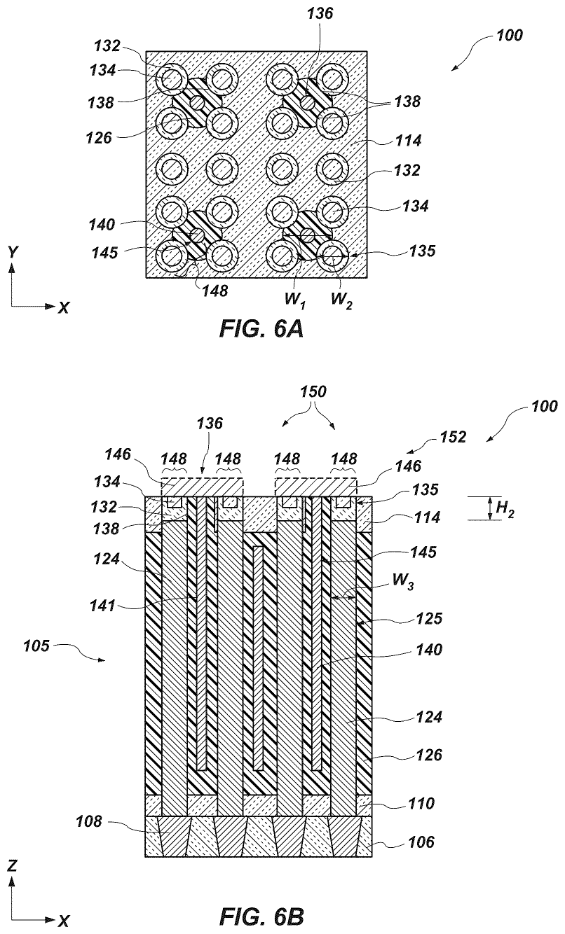

With reference to FIG. 1A in combination with FIG. 1B, the electronic device 100 may include a base material 102 (e.g., a substrate) and access devices 104 within the base material 102. For example, the access devices 104 may be laterally spaced from one another within the base material 102 and individually comprise a source region and a drain region. A support structure 105 adjacent to (e.g., overlying) the base material 102 may include a first insulative material 106 and conductive contacts 108 within openings in the first insulative material 106, although other configurations may be contemplated. The conductive contacts 108 connect the drain regions of individual access devices 104 to capacitors (e.g., capacitors 148 (FIG. 6B)) overlying the conductive contacts 108. The support structure 105 (e.g., a film stack) includes a second insulative material 110 adjacent to (e.g., over, directly on) the first insulative material 106 and the conductive contacts 108, a third insulative material 112 adjacent to (e.g., over, directly on) the second insulative material 110, and a fourth insulative material 114 (e.g., a lattice insulative material) adjacent to (e.g., over, directly on) the third insulative material 112. The fourth insulative material 114 may be configured as retaining structures (e.g., lattice structures) to provide structural support (e.g., structural stability) during formation of the capacitors that extend vertically through the support structure 105.

The base material 102 may include a conventional silicon substrate (e.g., a conventional silicon wafer), or another bulk substrate comprising a semiconductive material. As used herein, the term “bulk substrate” means and includes not only silicon substrates, but also silicon-on-insulator (SOI) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the base material 102 comprises a silicon wafer.

In some embodiments, the base material 102 includes different materials, structures, devices, and/or regions formed therein and/or thereon. In some embodiments, the base material 102 includes complementary metal-oxide-semiconductor (CMOS) circuitry and devices configured for effectuating operation of memory cells of the electronic device 100.

For illustrative purposes, a space (e.g., a gap) is shown between the base material 102 and the support structure 105 in FIG. 1B to indicate that additional materials and/or features may be between the base material 102 and the support structure 105. For example, additional conductive structures may be located between the access devices 104 and the conductive contacts 108. Further, the access devices 104 are illustrated in broken lines to indicate that at least some of the access devices 104 may be located in a different cross-section (e.g., a different plane) than the cross-section illustrated in FIG. 1B. For case of illustration and understanding, the base material 102 and the access devices 104 are not shown in subsequent drawings, although it is understood that the base material 102, the access devices 104, and the additional materials and features associated therewith may be present in the electronic device 100.

The first insulative material 106 may be formed of and include an insulative material, such as one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 106 comprises silicon dioxide.

The conductive contacts 108 may be formed of and include an electrically conductive material such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), alloys thereof, a conductively-doped semiconductor material (e.g., conductively-doped silicon, conductively-doped germanium, conductively-doped silicon germanium, etc.), polysilicon, or other materials exhibiting electrical conductivity. In some embodiments, the conductive contacts 108 comprise tungsten. In other embodiments, the conductive contacts 108 comprise TiN.

The second insulative material 110 may be formed of and include an insulative material that is different than (e.g., has a different chemical composition than), and exhibits an etch selectivity with respect to, the first insulative material 106. The second insulative material 110 may be formed of and include at least one dielectric nitride material (e.g., silicon nitride (Si₃N₄)), at least one oxynitride material (e.g., silicon oxynitride), a dielectric carbon nitride material (e.g., silicon carbon nitride (SiCN)), at least one dielectric carboxynitride material (e.g., silicon carboxynitride (SiOCN)), or combinations thereof. In some embodiments, the second insulative material 110 comprises silicon nitride. As used herein, the terms “selectively removable” or “selectively etchable” mean and include a material that exhibits a greater etch rate responsive to exposure to a given etch chemistry and/or process conditions (collectively referred to as etch conditions) relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

The third insulative material 112 (e.g., a first sacrificial material) may be formed of and include insulative material, such as one or more of the materials described above with reference to the first insulative material 106. As used herein, the term “sacrificial,” when used in reference to a material or structure, means and includes a material or structure that is formed during a fabrication process but which is removed (e.g., substantially removed) prior to completion of the fabrication process. In some embodiments, the third insulative material 112 comprises silicon dioxide. The fourth insulative material 114 may be formed of and include insulative material, such as one or more of the materials described above with reference to the second insulative material 110. In some embodiments, the fourth insulative material 114 comprises silicon nitride.

First openings 118 (e.g., lattice openings, central openings) may be formed to extend through the fourth insulative material 114 to expose upper surfaces of the third insulative material 112. Prior to formation of the first openings 118, an additional insulative material (e.g., an additional portion of the fourth insulative material 114) and/or a mask material 116 (e.g., a photoresist material, a carbon-containing mask material) may, optionally, be formed over the fourth insulative material 114. The additional insulative material may be configured and positioned to protect additional portions of the fourth insulative material 114 from being removed (e.g., etched) during formation of the first openings 118. In some embodiments, portions of the fourth insulative material 114 may be removed in a single (e.g., one) material removal act to reduce cost and the number of process acts conducted.

As shown in FIGS. 1A and 1B, a dielectric material 120 (e.g., a second sacrificial material) may be formed within the first openings 118. The dielectric material 120 may be formed of and include insulative material that is different than (e.g., has a different chemical composition than), and exhibits an etch selectivity with respect to, the fourth insulative material 114, such as one or more of the materials described above with reference to the first insulative material 106. In some embodiments, the dielectric material 120 includes a high quality silicon oxide material, such as an ALD SiOₓ. In some embodiments, the dielectric material 120 comprises silicon dioxide. The dielectric material 120 may or may not comprise substantially the same material composition as the third insulative material 112.

Following formation of the dielectric material 120, the electronic device 100 may, optionally, be subjected to, for example, a chemical mechanical planarization (CMP) process to remove material (e.g., additional portions of the dielectric material 120) overlying the fourth insulative material 114. In other embodiments, the dielectric material 120 may not be formed at the processing stage of FIGS. 1A and 1B, and the first openings 118 may remain open (e.g., substantially free of material) during subsequent processing acts. For example, one or more insulative materials (e.g., additional portions of the fourth insulative material 114, the mask material 116) may, optionally, be formed over the first openings 118 to protect underlying materials during the subsequent processing acts.

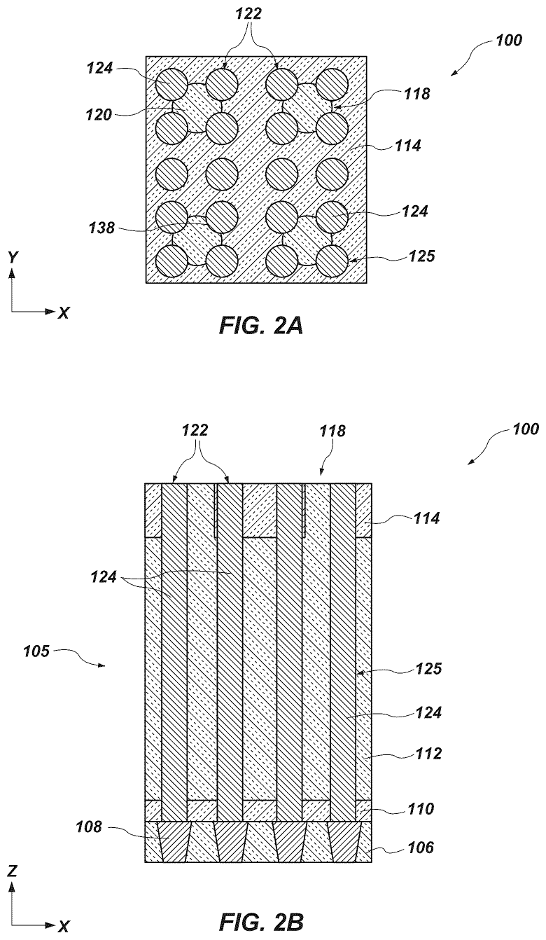

Referring to FIGS. 2A and 2B, following formation of the first openings 118 and, optionally, the dielectric material 120 therewithin, additional portions of the mask material 116, the fourth insulative material 114 and portions of the dielectric material 120, the third insulative material 112, and the second insulative material 110 may be removed to form second openings 122 adjacent to (e.g., in communication with) and partially overlapping (e.g., within horizontal boundaries of) the first openings 118. The second openings 122 may be formed to extend through the dielectric material 120, the fourth insulative material 114, the third insulative material 112, and the second insulative material 110 to expose upper surfaces of the conductive contacts 108. Accordingly, the second openings 122 are defined by side surfaces of the dielectric material 120, the fourth insulative material 114, the third insulative material 112, the second insulative material 110, and upper surfaces of the conductive contacts 108. Portions of the dielectric material 120, the fourth insulative material 114, the third insulative material 112, and the second insulative material 110 may be removed (e.g., etched) by exposing the materials to wet etch and/or dry etch chemistries, for example, in one or more material removal process acts, without substantially removing material of the conductive contacts 108.

As shown in FIG. 2A, portions of the second openings 122 partially overlap (e.g., partially horizontally overlap) the first openings 118 in at least one horizontal direction (e.g., the X-direction, the Y-direction). Since the second openings 122 are formed after forming the first openings 118 (e.g., after patterning the fourth insulative material 114) by removing portions of the fourth insulative material 114 and the dielectric material 120, the second openings 122 individually exhibit a substantially circular cross-sectional shape without recesses (e.g., voids, gaps) formed therein. Accordingly, the dielectric material 120 within the first openings 118 includes recessed regions 138 (e.g., notches, indentations), while the second openings 122 are substantially devoid of notches and/or indentations. A perimeter (e.g., a circumference) of individual second openings 122 is substantially even (e.g., substantially uniform, substantially regular), and a perimeter of individual first openings 118 is uneven (e.g., non-uniform, irregular) responsive to forming the second openings 122 after forming the first openings 118.

While the second openings 122 are illustrated as being formed after formation of the first openings 118 for clarity and ease of understanding of the drawings and related description, the second openings 122 may, alternatively, be formed before or, alternatively, during (e.g., substantially simultaneous with) formation of the first openings 118, so long as the first openings 118 are formed prior to formation of subsequently formed features (e.g., leaker devices) of the electronic device 100.

As shown in FIG. 2A, more than one (e.g., two or more, four) of the second openings 122 may be associated with one of the first openings 118. In some embodiments, additional second openings 122 may be remote (e.g., isolated) from the first openings 118 by the fourth insulative material 114. For example, one or more (e.g., two) of the second openings 122 may laterally intervene between adjacent first openings 118 and associated second openings 122 in at least one horizontal direction (e.g., the Y-direction), although other configurations may be contemplated.

As shown in FIGS. 2A and 2B, a first electrode material 124 may be formed within the second openings 122 to form first electrodes 125 (e.g., bottom electrodes of capacitors). The first electrode material 124 and, thus, the first electrodes 125 may be formed directly adjacent (e.g., directly on) the upper surfaces of the conductive contacts 108. The first electrodes 125 may individually be configured as conductive pillars (e.g., studs). The conductive pillars of the first electrodes 125, in combination with the fourth insulative material 114, may be configured to provide structural support to the support structure 105 during formation of the capacitors, as well as during use and operation of the electronic device 100.

Since the second openings 122 are formed after forming the first openings 118, the first electrodes 125 may be formed adjacent to and partially overlapping the first openings 118 including the dielectric material 120. The first electrodes 125 individually exhibit a substantially circular cross-sectional shape in a direction that is transverse to a direction in which the first electrodes 125 extend through the support structure 105, without recesses (e.g., voids, gaps) formed therein. Accordingly, the dielectric material 120 within the first openings 118 includes the recessed regions 138 (e.g., notches, indentations), while the first electrodes 125 within the second openings 122 are substantially devoid of notches and/or indentations. A perimeter of individual first electrodes 125 is substantially even (e.g., substantially uniform, substantially regular), and a perimeter of individual portions of the dielectric material 120 is uneven (e.g., non-uniform, irregular) responsive to forming the second openings 122 after forming the first openings 118.

The first electrode material 124 may be formed of and include conductive material, such as one or more of the materials described above with reference to the conductive contacts 108. The first electrode material 124 of the first electrodes 125 may or may not comprise substantially the same material composition as the conductive contacts 108. In some embodiments the first electrode material 124 comprises a metal (e.g., titanium, tungsten, ruthenium, cobalt, nickel, platinum). In other embodiments the first electrode material 124 comprises a metal nitride material (e.g., TiN). Following formation of the first electrode material 124, the electronic device 100 may, optionally, be subjected to, for example, a CMP process to remove material (e.g., additional portions of the first electrode material 124) overlying the fourth insulative material 114.

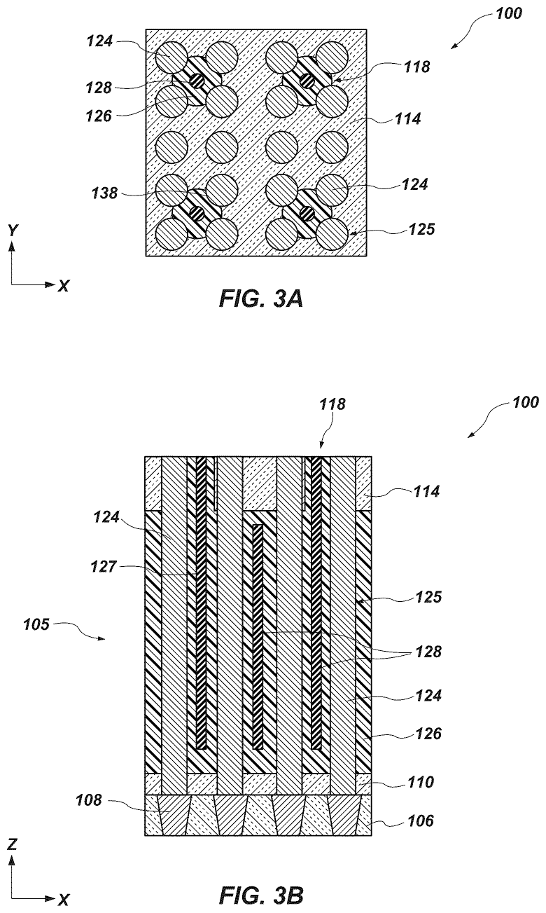

Referring to FIGS. 3A and 3B, after forming the first electrodes 125, the dielectric material 120 and the third insulative material 112 may be removed (e.g., etched) by exposing the materials to wet etch and/or dry etch chemistries, for example, in one or more material removal process acts, without substantially removing material of the second insulative material 110 and the fourth insulative material 114. In some embodiments, the dielectric material 120 and the third insulative material 112 may be removed in a single (e.g., one) material removal act to reduce cost and the number of process acts conducted.

An insulative material 126 (e.g., a cell insulative material) may be formed within locations vacated by the removal of the dielectric material 120 and the third insulative material 112. In some embodiments, the insulative material 126 is formed (e.g., conformally formed) adjacent to the first electrode material 124 within the first openings 118 without fully filling the first openings 118. Alternatively, the insulative material 126 may be formed (e.g., non-conformally formed) to initially fill (e.g., substantially entirely fill) the first openings 118. Thereafter, portions of the insulative material 126 remote from the first electrode material 124 may be selectively removed to form (e.g., reopen) central regions of the first openings 118.

The insulative material 126 may be formed of and include one or more of a transition metal oxide, silicon dioxide (SiO₂), titanium dioxide (TiO₂), tantalum oxide (Ta₂O₅), aluminum oxide (Al₂O₃), a nitride (e.g., silicon nitride (SiN)), an oxide-nitride-oxide material (e.g., silicon dioxide-silicon nitride-silicon dioxide), strontium titanate (SrTiO₃) (STO), barium titanate (BaTiO₃), hafnium oxide (HfO₂), niobium oxide (NbO), zirconium oxide (ZrO₂), a ferroelectric material (e.g., ferroelectric hafnium oxide, ferroelectric zirconium oxide, lead zirconate titanate (PZT)), a high-k dielectric material, or a combination thereof. The insulative material 126 may, for example, be formed of and include a stack (e.g., laminate) of at least two different high-k dielectric materials. In some embodiments, the insulative material 126 is doped with one or more dopants (e.g., silicon, aluminum, lanthanum, yttrium, erbium, calcium, magnesium, strontium). In some embodiments, portions (e.g., substantially an entirety) of the insulative material 126 may be formed of and include ferroelectric insulative material.

Following formation of the insulative material 126, a sacrificial material 128 (e.g., a third sacrificial material) may, optionally, be formed within the central regions of the first openings 118 and the additional regions underlying the fourth insulative material 114. The sacrificial material 128 may be configured and positioned to protect the materials (e.g., the insulative material 126), as well as subsequently formed materials (e.g., one or more materials of the leaker devices) from being removed (e.g., etched) during the subsequent material removal processes of the electronic device 100. The sacrificial material 128 may also provide structural support to the support structure 105 of the electronic device 100 during formation of the capacitors. The sacrificial material 128 may be adjacent to and substantially surrounded by the insulative material 126. As shown in FIG. 3B, one or more side surfaces (e.g., lateral side surfaces, horizontal side surfaces) of the sacrificial material 128 may directly contact side surfaces of the insulative material 126 along interfaces 127 (e.g., vertical interfaces).

The sacrificial material 128 may be formed of and include an insulative material such as, for example, one or more of an oxide material (e.g., silicon dioxide (SiO₂), titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof). In some embodiments, the sacrificial material 128 may be formed of and include one or more of a carbon-containing material (e.g., carbon-doped silicon nitride, silicon carbon nitride (SiCN)), a boron-containing material (e.g., boron-doped silicon nitride), or a gallium-containing material. In other embodiments, the sacrificial material 128 comprises amorphous silicon or polycrystalline silicon. By way of non-limiting example, the sacrificial material 128 may be formed of and include one or more of boron nitride (BN_{y}), gallium nitride (GaN), oxynitride material (e.g., SiOₓN_{y}), and carboxynitride material (e.g., SiOₓC_{z}N_{y}). In some embodiments, the sacrificial material 128 comprises silicon dioxide. In other embodiments, the sacrificial material 128 comprises aluminum oxide (e.g., undensified aluminum oxide). The sacrificial material 128 may exhibit an etch selectivity with respect to surrounding materials, including the insulative material 126.

In some embodiments, the sacrificial material 128 includes a high quality silicon oxide material, such as an ALD SiOₓ. The sacrificial material 128 may be substantially conformal as deposited and, thus, exhibit a substantially uniform thickness. For example, the sacrificial material 128 may be a substantially uniform and substantially conformal silicon oxide material (e.g., a highly uniform and highly conformal silicon dioxide material). The sacrificial material 128 may be formulated to be formed in HAR openings, such as those having a HAR of at least about 20:1, at least about 50:1, at least about 100:1, or at least about 1000:1, without forming voids. The sacrificial material 128 is formed by conventional techniques, such as by CVD, ALD, or plasma-enhanced ALD (PEALD). In other embodiments, the sacrificial material 128 may be formed within upper regions of the first openings 118 to effectively “pinch off” and close (e.g., seal) the central regions of the first openings 118 immediately adjacent to upper surfaces of the fourth insulative material 114, without fully filling additional regions (e.g., lower regions) of the first openings 118. In yet other embodiments, the sacrificial material 128 may not be formed at the processing stage of FIGS. 3A and 3B, and the first openings 118 may remain open (e.g., substantially free of material) during subsequent processing acts. For example, one or more insulative materials (e.g., a photoresist material, such as the mask material 116 (FIG. 1B)) may, optionally, be formed over the first openings 118 to protect underlying materials during the subsequent processing acts.

As shown in FIGS. 3A and 3B, portions of the insulative material 126 may be formed within the first openings 118, such as adjacent to side surfaces of the fourth insulative material 114 and the first electrode material 124 of the first electrodes 125. Additional portions of the insulative material 126 may be formed adjacent to (e.g., underlying) lower surfaces of the fourth insulative material 114 in locations remote (e.g., isolated) from the first openings 118. Following formation of the insulative material 126 and the sacrificial material 128, the electronic device 100 may, optionally, be subjected to, for example, a CMP process to remove material (e.g., additional portions of the insulative material 126 and the sacrificial material 128) overlying the fourth insulative material 114.

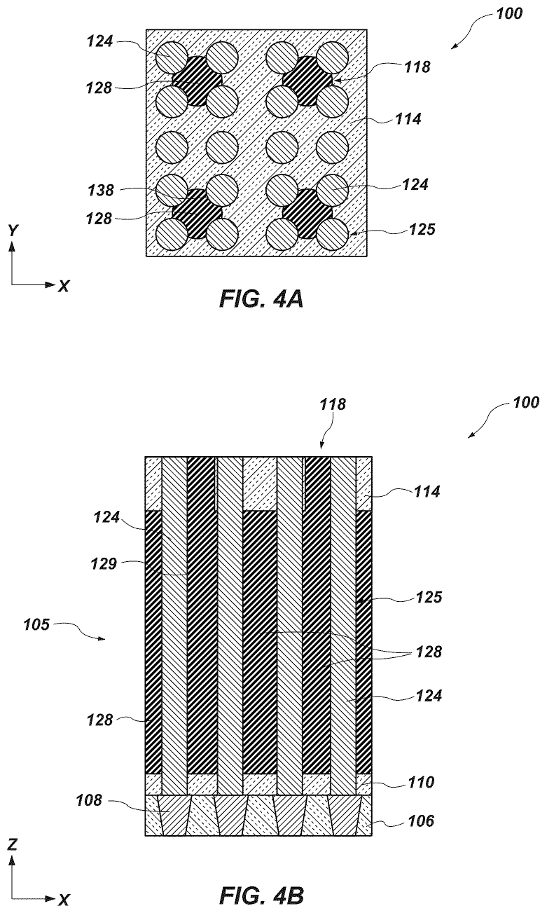

FIGS. 4A and 4B show a simplified, partial top-down view (FIG. 4A) and a simplified, partial cross-sectional view (FIG. 4B) of a method of forming the electronic device 100 using differing processing techniques. FIGS. 4A and 4B illustrate an additional embodiment of the electronic device 100 at the processing stage of FIGS. 3A and 3B. The electronic device 100 may include the first electrode material 124 of the first electrodes 125 adjacent to (e.g., overlying) the conductive contacts 108, and the fourth insulative material 114 adjacent to (e.g., laterally adjacent to) upper portions of the first electrode material 124.

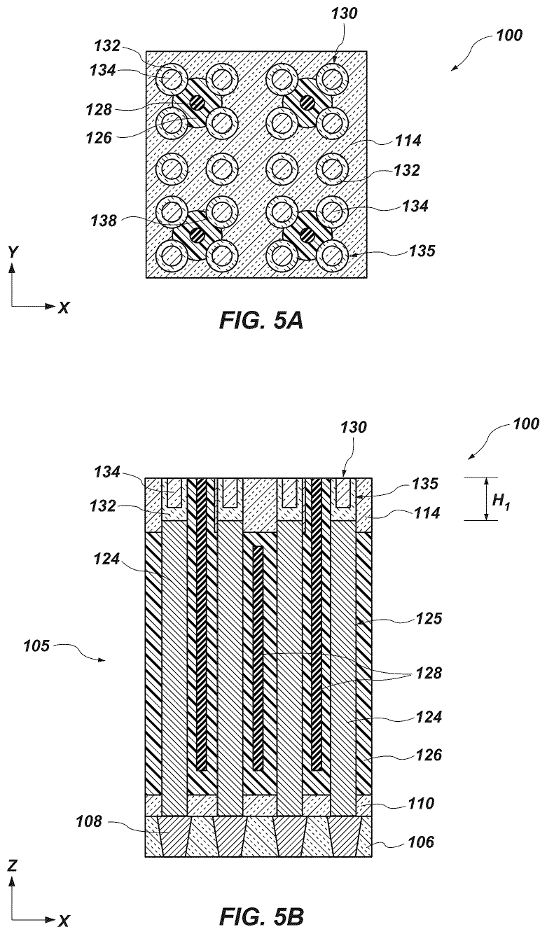

In the embodiment of FIGS. 4A and 4B, the insulative material 126 (FIGS. 3A and 3B) may not be formed following removal of the dielectric material 120 and the third insulative material 112. As shown in FIG. 4B, additional portions of the third insulative material 112 adjacent to (e.g., underlying) the fourth insulative material 114 may be removed prior to forming the sacrificial material 128. For example, the sacrificial material 128 may be formed within locations vacated by the removal of the dielectric material 120 and the third insulative material 112, without forming the insulative material 126 at the processing stage of FIGS. 4A and 4B. The sacrificial material 128 may be formed by removing additional portions of the third insulative material 112 in regions underlying the fourth insulative material 114. Portions of the sacrificial material 128 may be formed within the first openings 118, such as adjacent to side surfaces of the fourth insulative material 114 and the first electrode material 124 of the first electrodes 125. Additional portions of the sacrificial material 128 may be formed in the locations underlying the fourth insulative material 114, such as in locations vacated by the removal of the additional portions of the third insulative material 112. The insulative material 126 may be formed during a subsequent processing stage (e.g., at the processing stage of FIGS. 5A and 5B) following subsequent removal of the sacrificial material 128.

As shown in FIG. 4B, one or more side surfaces (e.g., lateral side surfaces, horizontal side surfaces) of the sacrificial material 128 may directly contact side surfaces of the first electrode material 124 of the first electrodes 125 along interfaces 129 (e.g., vertical interfaces). The sacrificial material 128 may be formed to substantially fully extend between the lower surfaces of the fourth insulative material 114 and upper surfaces of the second insulative material 110. Further, the sacrificial material 128 may be formed to substantially fully extend between adjacent portions of the first electrode material 124. The sacrificial material 128 may be formed adjacent to (e.g., directly laterally adjacent to) and substantially surrounding the first electrodes 125. Structural support (e.g., structural stability) of the support structure 105 may be enhanced by forming the sacrificial material 128 within the additional locations during formation of the electronic device 100.

In additional embodiments, the third insulative material 112 may remain in locations adjacent to (e.g., underlying) the fourth insulative material 114, and the sacrificial material 128 may be formed solely within the first openings 118. In some embodiments, the third insulative material 112 and the sacrificial material 128 may be formulated to be removed (e.g., etched) in a single (e.g., one) material removal act to reduce cost and the number of process acts conducted. Following formation of the sacrificial material 128, the electronic device 100 may, optionally, be subjected to, for example, a CMP process to remove material (e.g., additional portions of the sacrificial material 128) overlying the fourth insulative material 114.

Referring to FIGS. 5A and 5B, following formation of the sacrificial material 128, portions (e.g., the upper portions) of the first electrode material 124 of the first electrodes 125 may be removed (e.g., etched) to form recessed regions 130 of the first electrodes 125. Formation of the electronic device 100 at the processing stage of FIGS. 5A and 5B may be achieved by using the process acts of FIGS. 3A and 3B or, alternatively, the process acts of FIGS. 4A and 4B. The first electrode material 124 may be selectively removed by exposing the material to wet etch and/or dry etch chemistries, for example, in one or more material removal process acts, without substantially removing the fourth insulative material 114 and the insulative material 126. Accordingly, a lateral dimension (e.g., a width) of the recessed regions 130 is substantially the same as (e.g., substantially equal to) a lateral dimension of the underlying first electrodes 125. In other embodiments, portions of one or more of the fourth insulative material 114 and the insulative material 126 adjacent to the recessed regions 130 may be laterally recessed, with the lateral dimension of the recessed regions 130 relatively greater than the lateral dimension of the first electrodes 125. The recessed regions 130 are defined by side surfaces of the fourth insulative material 114 and the insulative material 126, and upper surfaces of remaining portions of the first electrode material 124 of the first electrodes 125.

As shown in FIGS. 5A and 5B, a leaker device material 132 (e.g., one or more conductive materials) may be formed (e.g., conformally formed) within the recessed regions 130 of the first electrodes 125, and a leaker liner material 134 (e.g., a leaker fill material) may be formed adjacent to the leaker device material 132 and within remaining regions (e.g., central regions) of the recessed regions 130. Formation of the leaker device material 132 and the leaker liner material 134 results in formation of leaker devices 135. As shown in FIG. 5B, lowermost boundaries of the leaker devices 135 are vertically elevated (e.g., in the Z-direction) above lower surfaces of the fourth insulative material 114. Thus, the lowermost boundaries of the leaker devices 135 are above upper surfaces of the insulative material 126 underlying the fourth insulative material 114. Stated another way, upper surfaces of the first electrodes 125 are vertically elevated above upper surfaces of the insulative material 126.

The leaker device material 132 may be formed of and include conductive material, such as one or more of titanium, tungsten, cobalt, nickel, platinum, ruthenium, and niobium, in combination with one or more of germanium, silicon, oxygen, nitrogen, and carbon. By way of non-limiting example, the leaker device material 132 may include one or more of silicon (Si), germanium (Ge), silicon nitride (SiN), silicon titanium nitride (TiSiN), titanium oxide (TiO), titanium nitride (TiN), nickel oxide (NiO), molybdenum nitride (MoN), and at least one dielectric oxynitride material (e.g., NiON, TiON). In some embodiments, the leaker device material 132 (e.g., a precursor material) may include one or more of titanium, oxygen, and nitrogen. The leaker device material 132 may comprise amorphous silicon, niobium oxide, silicon-rich silicon nitride, or a combination thereof. The leaker device material 132 may or may not include substantially the same material composition as the first electrode material 124 of the first electrodes 125. The leaker liner material 134 may be formed of and include insulative material, such as one or more of the materials described above with reference to the first insulative material 106 (e.g., silicon dioxide) or, alternatively, one or more of the materials described above with reference to the second insulative material 110 (e.g., silicon nitride). In other embodiments, the leaker liner material 134 comprises polycrystalline silicon. In additional embodiments, the leaker devices 135 may include a single material (e.g., the leaker device material 132).

The leaker device material 132 may initially be formed of a metal nitride material (e.g., titanium nitride). One or more of the leaker device material 132 and the leaker liner material 134 may, optionally, be subjected to (e.g., exposed to) one or more treatment acts that change a material composition of the materials of the leaker devices 135. As initially formed, the metal nitride material of the leaker device material 132 may have a first material composition exhibiting a first conductivity, and the leaker device material 132 may be changed (e.g., converted) to a second material composition exhibiting a second conductivity that is relatively less than the first conductivity. For example, the materials of the leaker devices 135 may be subjected to oxidizing conditions (e.g., using one or more of oxygen and hydrogen), although other treatment conditions may be contemplated.

The leaker devices 135 include the leaker device material 132 and the leaker liner material 134, if present. During initial formation of the materials of the leaker devices 135, the leaker liner material 134 may be substantially surrounded by the leaker device material 132. The leaker liner material 134 is separated (e.g., vertically separated) from the first electrode material 124 of the first electrodes 125 by the leaker device material 132, and the leaker device material 132 directly intervenes between the leaker liner material 134 and the first electrode material 124. Further, the leaker liner material 134 is separated (e.g., laterally separated) from the fourth insulative material 114 and portions of the insulative material 126 laterally adjacent to the fourth insulative material 114 by the leaker device material 132. Thus, the leaker device material 132 directly intervenes between the leaker liner material 134 and each of the fourth insulative material 114 and the insulative material 126. Since the sacrificial material 128 is within the central regions of the first openings 118 (FIG. 3A), the sacrificial material 128 is separated (e.g., laterally separated) from the leaker liner material 134 by the insulative material 126 at the processing stage of FIGS. 5A and 5B.

The leaker device material 132, as initially formed, may include substantially continuous portions. For example, the leaker device material 132 may be formed adjacent to (e.g., over, directly on) the first electrodes 125, and the leaker liner material 134 may be formed adjacent to (e.g., over, directly on) and substantially surrounded by the leaker device material 132. Following the one or more treatment acts that change a material composition of the materials of the leaker devices 135, the leaker device material 132 may, optionally, include discontinuous (e.g., segmented) portions to allow for the leaker devices 135 to exhibit sufficient conductivity during use and operation of the electronic device 100.

As shown in FIG. 5B, a depth of the recessed regions 130 may substantially correspond to an initial height of the leaker devices 135, including the leaker device material 132 and the leaker liner material 134. For example, the recessed regions 130 may be formed to have a desired depth that may be responsive to a first height H₁ (e.g., an initial height) of the leaker devices 135 (e.g., a height of the leaker devices 135 extending above the upper surfaces of the first electrodes 125) and on a desired height of the leaker devices 135 following subsequent processing of the electronic device 100, as described in greater detail below with reference to FIG. 6B. By way of non-limiting example, the first height H₁ of leaker devices 135, may be within a range of from about 30 nm to about 600 nm, such as from about 30 nm to about 100 nm, from about 100 nm to about 200 nm, from about 200 nm to about 300 nm, from about 300 nm to about 400 nm, from about 400 nm to about 500 nm, or from about 500 nm to about 600 nm. However, the disclosure is not so limited and the first height H₁ may be different than those described above.

Following formation of the leaker devices 135 including the leaker device material 132 and the leaker liner material 134, the electronic device 100 may, optionally, be subjected to, for example, a CMP process to remove material (e.g., additional portions of the leaker device material 132 and the leaker liner material 134) overlying the fourth insulative material 114. Accordingly, upper surfaces of each of the leaker liner material 134, the leaker device material 132, the sacrificial material 128, the insulative material 126, and the fourth insulative material 114 may be substantially coplanar with one another, as shown in FIG. 5B.

Referring to FIGS. 6A and 6B, after forming the leaker devices 135, the sacrificial material 128 (FIG. 5B) may be removed (e.g., etched) to form third openings 136. The sacrificial material 128 may be at least partially (e.g., substantially entirely) removed. For example, the electronic device 100 may be exposed to one or more etchants formulated and configured to selectively remove the sacrificial material 128 without substantially removing the insulative material 126. The sacrificial material 128 may, alternatively, be removed before formation of the leaker devices 135. By way of non-limiting example, the sacrificial material 128 may be exposed to one or more of a plasma including xenon difluoride (XF₂), chlorine (Cl₂) (e.g., a mixture of Cl₂, nitrogen (N₂), and argon (Ar)), fluorine (F₂), nitrogen trifluoride (NF₃), carbon tetrafluoride (CF₄), hydrogen fluoride (HF), or another material. However, the disclosure is not so limited and the sacrificial material 128 may be removed by methods other than those described above. The third openings 136 may be formed at locations vacated by the removal of the sacrificial material 128 (e.g., the central regions of the first openings 118 (FIG. 3B)). Since the sacrificial material 128 was substantially surrounded by the insulative material 126, the third openings 136 are defined by side surfaces and upper surfaces of the insulative material 126.

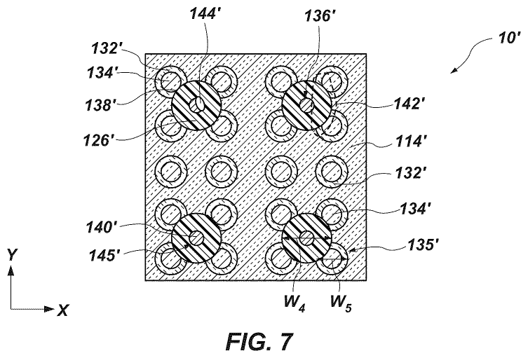

Since the second openings 122 are formed after forming the first openings 118, portions of the leaker devices 135 partially overlap (e.g., partially horizontally overlap) the insulative material 126 in at least one horizontal direction (e.g., the X-direction, the Y-direction), as shown in FIG. 6A. Once formed, lateral portions (e.g., horizontal portions) of the materials of the leaker devices 135 are not removed, which processes differ from that of formation of leaker devices of conventional electronic devices, as described in greater detail with reference to FIG. 7. Accordingly, the leaker devices 135 in electronic devices 100 according to embodiments of the disclosure individually exhibit a substantially circular cross-sectional shape in a direction that is transverse to a direction in which the leaker devices 135 extend through the fourth insulative material 114, without recesses (e.g., voids, gaps) formed therein. As shown in FIGS. 6A and 6B, the insulative material 126 includes the recessed regions 138 (e.g., notches, indentations), while the leaker devices 135 are substantially devoid of notches and/or indentations. A perimeter of individual leaker devices 135 is substantially even (e.g., substantially uniform, substantially regular), and a perimeter of individual portions of the insulative material 126 is uneven (e.g., non-uniform, irregular) and includes the recessed regions 138 responsive to forming the leaker devices 135 within the second openings 122 after forming the insulative material 126 within the first openings 118.

A second electrode material 140 (e.g., a conductive material) may be formed adjacent to the insulative material 126 and within the third openings 136. Formation of the second electrode material 140 results in formation of second electrodes 145 (e.g., top electrodes of capacitors). The second electrode material 140 is substantially laterally surrounded by the insulative material 126. A conductive material (e.g., the second electrode material 140) of the second electrodes 145 may be substantially surrounded by the insulative material 126, without additional portions of the conductive material extending beyond the insulative material 126. As shown in the top-down view of FIG. 6A, the second electrodes 145 may individually exhibit a substantially circular cross-sectional shape in a direction that is transverse to a direction in which the second electrodes 145 extend through the support structure 105. The second electrode material 140 is separated (e.g., laterally separated) from the first electrode material 124 of the first electrodes 125 by the insulative material 126, and the insulative material 126 directly intervenes between the second electrode material 140 and the first electrode material 124. Further, the second electrode material 140 is separated (e.g., laterally separated) from the fourth insulative material 114 by the insulative material 126. Thus, the insulative material 126 directly intervenes between the second electrode material 140 and the fourth insulative material 114. As shown in FIG. 6B, one or more side surfaces (e.g., lateral side surfaces, horizontal side surfaces) of the second electrode material 140 of the second electrodes 145 may directly contact side surfaces of the insulative material 126 along interfaces 141 (e.g., vertical interfaces).

The second electrode material 140 may be formed of and include conductive material. In some embodiments, the second electrode material 140 comprises one or more of the materials described above with reference to the conductive contacts 108. In some embodiments, the second electrode material 140 of the second electrodes 145 comprises substantially the same material composition as the first electrode material 124 of the first electrodes 125 (e.g., titanium, tungsten, ruthenium, cobalt, nickel, platinum, TiN). The second electrode material 140 may or may not include substantially the same material composition as the leaker device material 132 of the leaker devices 135.

Following formation of the second electrodes 145, the electronic device 100 may, optionally, be subjected to, for example, a CMP process to remove material (e.g., additional portions of the second electrode material 140) overlying the fourth insulative material 114. Accordingly, upper surfaces of each of the second electrode material 140 of the second electrodes 145, the insulative material 126, the leaker devices 135, including the leaker device material 132 and the leaker liner material 134, and the fourth insulative material 114 may be substantially coplanar with one another, as shown in FIG. 6B. The upper surfaces of the first electrodes 125 are vertically recessed relative to the upper surfaces of the second electrodes 145.

While a lateral dimension (e.g., in the X-direction, in the Y-direction) of individual second electrodes 145 is illustrated for clarity as being relatively less than a thickness of the insulative material 126, the disclosure is not so limited. For example, the thickness (e.g., between an inner lateral boundary and an outer lateral boundary) of the insulative material 126 may appear enlarged relative to the lateral dimension of an associated second electrode 145 for clarity and case of understanding of the drawings and related description. However, it will be understood that the lateral dimension of the individual second electrodes 145 may be relatively greater than the thickness of the insulative material 126, so long as the second electrodes 145 are separated from and, thus, isolated from the leaker devices 135 and the first electrodes 125 by the insulative material 126. By way of non-limiting example, the thickness of the insulative material 126 may be within a range of from about 3 nm to about 25 nm.

As shown in FIG. 6A, a lateral dimension (e.g., a first width W₁, a diameter in the X-direction) of the insulative material 126 (corresponding to a lateral dimension of the first openings 118 (FIG. 1A)) may be relatively greater than a lateral dimension (e.g., a second width W₂, a diameter in the X-direction) of an individual leaker device 135 (corresponding to a lateral dimension of the second openings 122 (FIG. 2A)). By way of non-limiting example, the first width W₁ may be within a range of from about 20 nm to about 80 nm, such as from about 20 nm to about 30 nm, from about 30 nm to about 40 nm, from about 40 nm to about 50 nm, from about 50 nm to about 60 nm, from about 60 nm to about 70 nm, or from about 70 nm to about 80 nm. The second width W₂ may be within a range of from about 10 nm to about 30 nm, such as from about 10 nm to about 15 nm, from about 15 nm to about 20 nm, from about 20 nm to about 25 nm, or from about 25 nm to about 30 nm. In some embodiments, the first width W₁ is at least about 30 nm (e.g., within a range of from about 30 nm to about 60 nm, within a range of from about 50 nm to about 80 nm). Further, the first width W₁ of the insulative material 126 may be at least about two times (2×) the thickness of the insulative material 126 in order to provide adequate area for the second electrode 145. However, the disclosure is not so limited and the first width W₁ and the second width W₂ may be different than those described above. In some embodiments, the second width W₂ of the leaker devices 135 is substantially uniform around an entire perimeter of the leaker devices 135. Thus, an outer boundary of an individual leaker device 135 is at substantially equal distances from a center thereof around an entire perimeter of the individual leaker device 135.

As shown in FIG. 6B, the first electrodes 125 (including the first electrode material 124) may exhibit a lateral dimension (e.g., a third width W₃, a diameter in the X-direction). The third width W₃ may be substantially the same as (e.g., substantially equal to) the second width W₂ (FIG. 6A), such that outermost boundaries (e.g., lateral boundaries) of the first electrodes 125 and the leaker devices 135 are substantially the same as one another. Accordingly, the materials (e.g., the leaker device material 132, the leaker liner material 134) of the leaker devices 135 may be located adjacent to (e.g., over) the first electrode material 124 of the first electrodes 125, without the materials of the leaker devices 135 being located adjacent to (e.g., over) the insulative material 126. In additional embodiments, the third width W₃ may be relatively greater than or, alternatively, relatively less than the second width W₂.

Further, the leaker devices 135 may individually exhibit a second height H₂ that is relatively less than the first height H₁ thereof (FIG. 5B). The second height H₂ of the leaker devices 135, following subsequent processing of the electronic device 100 (e.g., the CMP process), may be within a range of from about 30 nm to about 300 nm, such as from about 30 nm to about 50 nm, from about 50 nm to about 100 nm, from about 100 nm to about 200 nm, or from about 200 nm to about 300 nm. In some embodiments, the second height H₂ is within a range of from about 50 nm to about 100 nm (e.g., about 85 nm). In other embodiments, the second height H₂ may be within a range of from about 0.2 nm (2 angstroms (Å)) to about 2 nm. However, the disclosure is not so limited and the second height H₂ may be different than those described above. The second height H₂ of the leaker devices 135 may be responsive, at least in part, to the materials (e.g., conductive materials) of the leaker devices 135, as well as a desired electrical resistance thereof during use and operation of the electronic device 100.

As shown in FIG. 6B, conductive structures 146 (e.g., conductive plate structures, conductive plate lines) may be formed adjacent to (e.g., over, directly on) the planarized surface of the materials of the support structure 105. The conductive structures 146 may be adjacent to (e.g., over, directly on) the leaker devices 135, including the leaker device material 132 and the leaker liner material 134. The leaker devices 135 couple the first electrodes 125 to the conductive structures 146 to allow discharge of at least a portion of any excess charge from the access devices 104 (FIG. 1B) passing through the first electrodes 125 to the conductive structures 146, without allowing (e.g., promoting) buildup of excess charge within the insulative material 126 during off current (I_{off}) of an individual memory cell. In some embodiments, the electrical resistance of the leaker devices 135 may be tailored to exhibit sufficient conductivity to remove excess charge from the first electrodes 125, while exhibiting low enough conductivity (e.g., high enough resistance) to substantially prevent the risk of undesirable short circuits between the first electrodes 125 and the conductive structures 146 during use and operation of the electronic device 100. Thus, the leaker devices 135 may be considered so-called “resistive interconnects” configured to couple the first electrodes 125 within individual memory cells to the conductive structures 146.

The conductive structures 146 may be formed of and include conductive material, such as one or more of the materials described above with reference to the conductive contacts 108. The conductive structures 146 may or may not comprise substantially the same material composition as one or more of the conductive contacts 108, the first electrodes 125, and the second electrodes 145 (e.g., titanium, tungsten, ruthenium, cobalt, nickel, platinum, TiN). In some embodiments, the conductive structures 146 is formed of and includes tungsten and the second electrode material 140 of the second electrodes 145 is formed of an includes titanium nitride.

While two of the conductive structures 146 are illustrated for clarity in FIG. 6B, the disclosure is not so limited. In other embodiments, additional (e.g., three of more) of the conductive structures 146 may be formed adjacent to (e.g., over, directly on) the second electrodes 145. Further, the conductive structures 146 are illustrated in broken lines to indicate that at least some of the conductive structures 146 may be located in a different cross-section (e.g., a different plane) than the cross-section illustrated in FIG. 6B.

Formation of the second electrodes 145 results in formation of the capacitors 148. The capacitors 148 include the first electrodes 125 (also referred to herein as “bottom electrodes,” “outer electrodes,” or “first electrode plates”), the second electrodes 145 (also referred to herein as “top electrodes,” “inner electrodes,” or “second electrode plates”), and the insulative material 126 between the first electrodes 125 and the second electrodes 145. The capacitors 148 may individually be coupled to one of the access devices 104 (FIG. 1B) within the base material 102 (FIG. 1B) through the conductive contacts 108. The electronic device 100 may include memory cells 150 within an array region of at least one memory array 152 vertically overlying (e.g., in the Z-direction) the base material 102. Each of the memory cells 150 may individually comprise an access device 104 (e.g., an access transistor) coupled to one of the capacitors 148. In some embodiments, the insulative material 126 of the memory cells 150 may include one or more of a transition metal oxide, a nitride, and a high-k dielectric material, although other configurations may be contemplated. For example, the memory cells 150 may include ferroelectric memory cells within a Ferroelectric Random Access Memory (FeRAM) of the memory array 152.

Accordingly, an electronic device comprises a memory array comprising access lines, data lines, and memory cells. Each memory cell is coupled to an associated access line and an associated data line and each memory cell comprises an access device, and a capacitor adjacent to the access device. The capacitor comprises a first electrode, a second electrode separated from the first electrode by an insulative material, and a leaker device adjacent to the first electrode. The second electrode and the leaker device extend through a lattice insulative material adjacent to the first electrode. The leaker device exhibits a substantially circular cross-sectional shape in a direction that is transverse to a direction in which the leaker device extends, with portions of the leaker device extending within a recessed region of the insulative material.

Accordingly, a method of forming an electronic device is disclosed. The method comprises forming a lattice insulative material adjacent to a first sacrificial material overlying conductive contacts, removing portions of the lattice insulative material to form first openings and to expose the first sacrificial material, removing additional portions of the lattice insulative material and portions of the first sacrificial material to form second openings and to expose the conductive contacts, forming a first electrode material within the second openings, forming an insulative material adjacent to the first electrode material, and forming a second sacrificial material within the first openings. The method comprises forming leaker devices adjacent to the first electrode material, removing the second sacrificial material, and forming a second electrode material adjacent to the insulative material in locations vacated by the removal of the second sacrificial material to form capacitors.

Accordingly, a method of forming an electronic device according to additional embodiments of the disclosure is disclosed. The method comprises forming central openings extending through a lattice insulative material, forming first electrodes adjacent to and partially overlapping the central openings, forming leaker devices adjacent to the first electrodes, and forming second electrodes adjacent to the first electrodes to form capacitors.

Forming the first openings 118 (e.g., lattice openings, central openings) prior to forming the recessed regions 130 of the first electrodes 125 and prior to forming the leaker devices 135 may facilitate improved performance of the electronic device 100 according to embodiments of the disclosure. For example, by patterning the fourth insulative material 114 (e.g., a lattice insulative material) prior to forming the first electrodes 125 within the second openings 122 and prior to forming the leaker devices 135 within the recessed regions 130 of the first electrodes 125, damage to the surrounding materials (e.g., the leaker device material 132 and the leaker liner material 134 of the leaker devices 135, the insulative material 126) may be reduced. In addition, by patterning the fourth insulative material 114 prior to forming the first electrodes 125 and the leaker devices 135, manufacturing processes may be simplified (e.g., without the need to form complex patterns in subsequently formed materials).

Further, the presence of the sacrificial material 128 within the central regions of the first openings 118 during formation of the leaker devices 135 may reduce damage to the materials of the leaker devices 135 and the insulative material 126. The second electrode material 140 of the second electrodes 145 of the electronic device 100 may be formed within the third openings 136 (e.g., corresponding to the central regions of the first openings 118) following removal of the sacrificial material 128, without being formed in damaged regions (e.g., voids) in the surrounding materials that may have occurred if the lattice openings of the first openings 118 were to be formed after formation of the leaker devices 135. Thus, the second electrode material 140 of the second electrodes 145 may be formed solely within the third openings 136, facilitating a reduction in leakage of charge during use and operation of the electronic device 100. For example, by isolating adjacent portions of the second electrodes 145 from one another, the leakage and, thus, so-called “disturb” of the memory cells 150 associated with adjacent capacitors 148 may be reduced.

In contrast, conventional processes used to form a conventional electronic device 10′, as shown in FIG. 7, which is a simplified, partial top-down view of a conventional electronic device 10′ at a similar stage of fabrication as the electronic device 100 of FIGS. 6A and 6B, may include forming lattice openings of the insulative material 126′ by patterning the fourth insulative material 114′ after forming conventional leaker devices 135′. In such devices, the leaker devices 135′ may be susceptible to damage during the conventional processes used to form the lattice openings after forming the leaker devices 135′, which may result in damage to surrounding materials during subsequent process acts and/or during use and operation of the conventional electronic device 10′. For example, additional portions of one or more of the leaker device material 132′, the leaker liner material 134′, and the insulative material 126′ may be damaged (e.g., removed) during material removal processes used to form the lattice openings. Thereafter, portions of a conductive material (e.g., the second electrode material 140′) of the second electrodes 145′ may be formed within the regions previously occupied by the additional portions of the surrounding materials. As shown in FIG. 7, the second electrode material 140′ of the second electrodes 145′ may not be located solely within (e.g., contained within) the third openings 136′, as illustrated in broken lines to indicate additional regions that may include additional portions of the second electrode material 140′. In some instances, the so-called leakage and/or parasitic currents may occur within adjacent capacitors during use and operation of the conventional electronic device 10′, which may adversely affect memory device performance.

Since openings of the leaker devices 135′ are formed prior to forming the lattice openings, portions of the insulative material 126′ partially overlap (e.g., partially horizontally overlap) the leaker devices 135′ in at least one horizontal direction (e.g., the X-direction, the Y-direction). In the conventional electronic device 10′, lateral portions (e.g., horizontal portions) of the materials of the leaker devices 135′ are removed, which processes differ from that of the electronic device 100 of FIGS. 1A through 6B. Accordingly, individual portions of the insulative material 126′ exhibit a substantially circular cross-sectional shape in a direction that is transverse to a direction in which the insulative material 126′ extends through the fourth insulative material 114, without recesses (e.g., voids, gaps) formed therein, and the leaker devices 135′ individually include recessed regions 138′ (e.g., notches, indentations). Further, a perimeter (e.g., a circumference) of the individual portions of the insulative material 126′ is substantially even (e.g., substantially uniform, substantially regular), and a perimeter of individual leaker devices 135′ is uneven (e.g., non-uniform, irregular) responsive to forming the leaker devices 135′ prior to patterning the fourth insulative material 114′.

In contrast to the recessed regions 138 of the electronic device 100 illustrated in FIGS. 6A and 6B, the recessed regions 138′ of the conventional electronic device 10′ are formed within the leaker devices 135′, rather than being formed within the insulative material 126′, which may result in damage to the surrounding materials (e.g., the leaker device material 132′ and the leaker liner material 134′ of the leaker devices 135′, the insulative material 126′) in the conventional electronic device 10′.

As shown in FIG. 7, a lateral dimension (e.g., a fourth width W₄, a diameter in the X-direction) of the insulative material 126′ may be substantially equal to or, alternatively, relatively greater than a lateral dimension (e.g., a fifth width W₅, a diameter in the X-direction) of an individual leaker device 135′. Further, the fourth width W₄ of the insulative material 126′ of the conventional electronic device 10′ may be relatively less than the first width W₁ (FIG. 6A) of the insulative material 126 (FIG. 6A) of the electronic device 100 according to embodiments of the disclosure illustrated in FIGS. 1A and 6B. For example, the fourth width W₄ of the insulative material 126′ of the conventional electronic device 10′ may be less than about 30 nm (e.g., less than about 25 nm) and the first width W₁ (FIG. 6A) of the insulative material 126 (FIG. 6A) of the electronic device 100 may be greater than about 30 nm (e.g., within a range of from about 30 nm to about 60 nm, within a range of from about 50 nm to about 80 nm). Since the leaker devices 135′ of the conventional electronic device 10′ are formed prior to patterning the fourth insulative material 114′, the lateral dimension of the fourth width W₄ of the insulative material 126′ is constrained (e.g., limited) to avoid overetch of the materials of the leaker devices 135′. In contrast, the lateral dimension of the first width W₁ of the insulative material 126 of the electronic device 100 is not constrained responsive to the fourth insulative material 114 (FIG. 6A) being patterned prior to formation of the leaker devices 135 (FIG. 6A).

As shown in FIG. 7, formation of the leaker devices 135′ prior to patterning the fourth insulative material 114′ may result in additional portions 142′ of the second electrode material 140′ being formed within damaged regions (e.g., within regions previously occupied by the insulative material 126′ and materials of the leaker devices 135′) that may have been removed during the process acts to pattern the fourth insulative material 114′, as illustrated in broken lines. Formation of the additional portions 142′ of the second electrode material 140′ may result in undesirable short circuits between the first electrodes 125′ (not shown) and the conductive structures coupled thereto during use and operation of the conventional electronic device 10′. For example, a different (e.g., relatively lower, relatively higher) conductivity and/or a different (e.g., relatively higher, relatively lower) resistance of the leaker devices 135′, compared to that of undamaged leaker devices, may be responsive to a reduction in amounts of the materials of the leaker devices 135′ and/or the additional portions 142′ of the second electrode material 140′ formed within the damaged regions. The leaker devices 135′ having the damaged regions may alter one or more of electrical property (e.g., conductivity, resistance) of the leaker devices 135′, an amount of excess charge that the leaker devices 135′ are able to discharge from the first electrodes 125′ to the conductive structures, and a rate at which the leaker devices 135 are able to discharge the excess charge.

Further, conventional processes used to form conventional electronic devices may result in damaged regions (e.g., voids 144′) being formed in the second electrode material 140′ of the second electrodes 145′, without the second electrode material 140′ fully filling the third openings 136′, as shown in FIG. 7. Since the additional portions 142′ of the second electrode material 140′ are formed within the damaged regions of the surrounding materials, sufficient amounts of the second electrode material 140′ may not be present within the openings of the second electrodes 145′. The voids 144′ may result in a disconnect region (e.g., a gap) between one or more of the second electrodes 145′ (e.g., top electrodes) of the capacitors and the conductive structures (corresponding to the conductive structures 146 (FIG. 6B)) coupled thereto. In some instances, the voids 144′ may result in inadequate contact (e.g., electrical contact, direct physical contact) between the second electrodes 145′ and the overlying conductive structures during use and operation of the conventional electronic device 10′, which may adversely affect memory device performance.

Accordingly, the presence of the additional portions 142′ of the second electrode material 140′ within damaged regions of the surrounding materials may lead to diminished insulative properties of the insulative material 126′ of the conventional electronic device 10′ in the region between the second electrodes 145′ and the leaker devices 135′ by such regions being occupied by the conductive material of the second electrode material 140′. The voids 144′ in the second electrode material 140′ may be responsive to the additional portions 142′ thereof being adjacent to and/or within horizontal boundaries of the insulative material 126′ and the leaker devices 135′ of the conventional electronic device 10′.

The electronic device 100 and methods according to embodiments of the disclosure illustrated in FIGS. 1A through 6B substantially reduce the occurrence of such unintended damage to the insulative material 126 and the materials of the leaker devices 135 by forming the lattice openings of the first openings 118 prior to forming the leaker devices 135. The presence of the sacrificial material 128 within locations designated for subsequent formation of the second electrode material 140 of the second electrodes 145 may reduce damage to the surrounding materials, without substantially affecting cell performance. Thus, integrity of the leaker devices 135 may be preserved and device performance may be enhanced by maintaining desired electrical resistance of the leaker devices 135 during use and operation of the electronic device 100.

Although the electronic device 100 is described herein as including a memory device including a memory array of a memory device (e.g., a DRAM memory device, a FeRAM memory device), the disclosure is not so limited. By way of non-limiting example, the electronic device 100 may be used within additional memory devices including FLASH memory configured as a not-and (NAND), not-or (NOR), 3D XPoint memory devices, or other memory devices (e.g., other DRAM devices including arrays of DRAM cells, 2D or 3D memory array structures, and cross-point memory (MTX) devices including cross-point memory arrays). Such configurations may facilitate a higher density of the memory array relative to conventional memory devices.

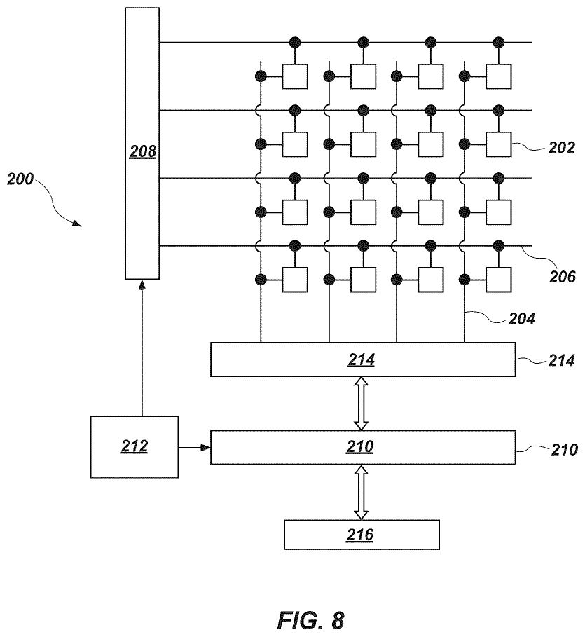

The electronic device 100 may be subjected to additional processing acts, as desired, to form an electronic device 200 (e.g., a microelectronic device, a memory device) including the electronic device 100, as shown in FIG. 8. Such additional processing may employ conventional processes and conventional processing equipment. The electronic device 200 may include, for example, embodiments of the electronic device 100 previously described herein. As shown in FIG. 8, the electronic device 200 may include memory cells 202 (e.g., corresponding to the memory cells 150 (FIG. 6B)), data lines 204 (e.g., digit lines, bit lines), access lines 206 (e.g., word lines), a row decoder 208, a column decoder 210, a memory controller 212, a sense device 214, and an input/output device 216.

The memory cells 202 of the electronic device 200 are programmable to at least two different logic states (e.g., logic 0 and logic 1). Each memory cell 202 may individually include a capacitor and transistor (not shown). The capacitor stores a charge representative of the programmable logic state (e.g., a charged capacitor may represent a first logic state, such as a logic 1; and an uncharged capacitor may represent a second logic state, such as a logic 0) of the memory cell 202. The transistor grants access to the capacitor responsive to application (e.g., by way of one of the access lines 206) of a minimum threshold voltage to a semiconductive channel thereof for operations (e.g., reading, writing, rewriting) on the capacitor.

The data lines 204 are connected to the capacitors of the memory cells 202 by way of the transistors of the memory cells 202. The access lines 206 extend perpendicular to the data lines 204, and are connected to gates of the transistors of the memory cells 202. Operations may be performed on the memory cells 202 by activating appropriate data lines 204 and access lines 206. Activating a data line 204 or an access line 206 may include applying a voltage potential to the data line 204 or the access line 206. Each column of memory cells 202 may individually be connected to one of the data lines 204, and each row of the memory cells 202 may individually be connected to one of the access lines 206. Individual memory cells 202 may be addressed and accessed through the intersections (e.g., cross points) of the data lines 204 and the access lines 206.

The memory controller 212 may control the operations of the memory cells 202 through various components, including the row decoder 208, the column decoder 210, and the sense device 214. The memory controller 212 may generate row address signals that are directed to the row decoder 208 to activate (e.g., apply a voltage potential to) predetermined access lines 206, and may generate column address signals that are directed to the column decoder 210 to activate (e.g., apply a voltage potential to) predetermined data lines 204. The memory controller 212 may also generate and control various voltage potentials employed during the operation of the electronic device 200. In general, the amplitude, shape, and/or duration of an applied voltage may be adjusted (e.g., varied), and may be different for various operations of the electronic device 200.

During use and operation of the electronic device 200, after being accessed, a memory cell 202 may be read (e.g., sensed) by the sense device 214. The sense device 214 may compare a signal (e.g., a voltage) of an appropriate data line 204 to a reference signal in order to determine the logic state of the memory cell 202. If, for example, the data line 204 has a relatively higher voltage than the reference voltage, the sense device 214 may determine that the stored logic state of the memory cell 202 is a logic 1, and vice versa. The sense device 214 may include transistors and amplifiers to detect and amplify a difference in the signals. The detected logic state of a memory cell 202 may be output through the column decoder 210 to the input/output device 216. In addition, a memory cell 202 may be set (e.g., written) by similarly activating an appropriate access line 206 and an appropriate data line 204 of the electronic device 200. By controlling the data line 204 while the access line 206 is activated, the memory cell 202 may be set (e.g., a logic value may be stored in the memory cell 202). The column decoder 210 may accept data from the input/output device 216 to be written to the memory cells 202. Furthermore, a memory cell 202 may also be refreshed (e.g., recharged) by reading the memory cell 202. The read operation will place the contents of the memory cell 202 on the appropriate data line 204, which is then pulled up to full level (e.g., full charge or discharge) by the sense device 214. When the access line 206 associated with the memory cell 202 is deactivated, all of memory cells 202 in the row associated with the access line 206 are restored to full charge or discharge.

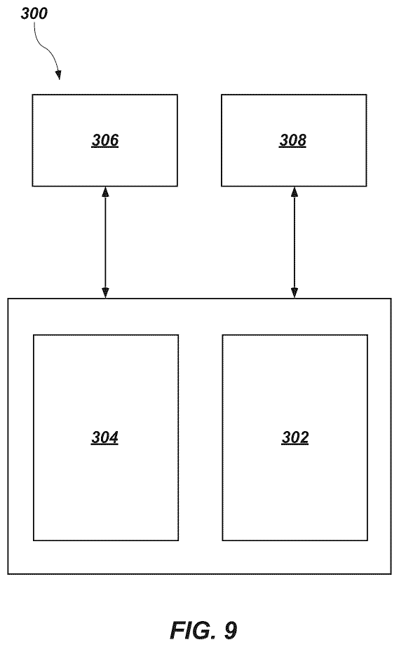

The electronic device 100 according to embodiments of the disclosure may be used in embodiments of electronic systems of the disclosure. For example, FIG. 9 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one electronic device 200. The electronic device 200 may comprise, for example, an embodiment of one or more of the electronic devices 100 previously described herein. The electronic system 300 may further include at least one electronic signal processor device 304 (often referred to as a “microprocessor”). The electronic signal processor device 304 may, optionally, include an embodiment of the electronic device 100 previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that may be used both to input information to the electronic system 300 and to output visual information to a user. The input device 306 and the output device 308 may communicate electrically with one or more of the electronic device 302 and the electronic signal processor device 304.

While the disclosure is susceptible to various modifications and alternative forms, specific embodiments have been shown by way of example in the drawings and have been described in detail herein. However, the disclosure is not intended to be limited to the particular forms disclosed. Rather, the disclosure is to cover all modifications, equivalents, and alternatives falling within the scope of the disclosure as defined by the following appended claims and their legal equivalents.

What is claimed is:

1. An electronic device comprising:
a memory array comprising access lines, data lines, and memory cells, each memory cell coupled to an associated access line and an associated data line and each memory cell comprising:
an access device;
a capacitor adjacent to the access device, the capacitor comprising:
a first electrode;
a second electrode separated from the first electrode by an insulative material; and
a leaker device adjacent to the first electrode, the second electrode and the leaker device extending through a lattice insulative material adjacent to the first electrode, and the leaker device exhibiting a substantially circular cross-sectional shape in a direction that is transverse to a direction in which the leaker device extends, with portions of the leaker device extending within a recessed region of the insulative material.

2. The electronic device of claim 1, wherein two or more leaker devices are associated with the second electrode, each of the two or more leaker devices extending within one of the recessed regions of the insulative material.

3. The electronic device of claim 1, further comprising a conductive structure adjacent to the leaker device, the leaker device configured to discharge excess charge from the first electrode to the conductive structure.

4. The electronic device of claim 1, wherein an outer boundary of the leaker device is at substantially equal distances from a center thereof around an entire perimeter of the leaker device.

5. The electronic device of claim 1, wherein a lateral dimension of the insulative material is relatively greater than a lateral dimension of the leaker device, the lateral dimension of the insulative material within a range of from about 50 nm to about 80 nm.

6. The electronic device of claim 1, wherein the second electrode exhibits a substantially circular cross-sectional shape in a direction that is transverse to a direction in which the second electrode extends, a conductive material of the second electrode substantially surrounded by the insulative material, without additional portions of the conductive material extending beyond the insulative material.

7. A method of forming an electronic device, the method comprising:
forming a lattice insulative material adjacent to a first sacrificial material overlying conductive contacts;
removing portions of the lattice insulative material to form first openings and to expose the first sacrificial material;
removing additional portions of the lattice insulative material and the first sacrificial material to form second openings and to expose the conductive contacts;
forming a first electrode material within the second openings;
forming an insulative material adjacent to the first electrode material;
forming a second sacrificial material within the first openings;
forming leaker devices adjacent to the first electrode material;
removing the second sacrificial material from the first openings; and
forming a second electrode material adjacent to the insulative material in locations vacated by the removal of the second sacrificial material to form capacitors.

8. The method of claim 7, wherein forming the first openings comprises patterning the lattice insulative material prior to forming the first electrode material and the leaker devices.

9. The method of claim 7, wherein forming the leaker devices comprises:
forming a metal nitride material having a first material composition exhibiting a first conductivity adjacent to upper surfaces of the first electrode material; and
performing one or more treatment acts to change the first material composition to a second material composition exhibiting a second conductivity that is relatively less than the first conductivity.

10. The method of claim 7, further comprising forming an additional sacrificial material within the first openings prior to forming the second openings, wherein forming the second openings comprises removing portions of the lattice insulative material and the additional sacrificial material.

11. The method of claim 7, wherein forming the second sacrificial material comprises forming an oxide material within central regions of the first openings, the oxide material directly contacting and substantially surrounded by the insulative material.

12. The method of claim 7, wherein the first openings are formed prior to forming the second openings, the first openings exhibiting a width that is relatively greater than a width of each of the second openings.

13. The method of claim 7, wherein forming the second sacrificial material comprises:
removing additional portions of the first sacrificial material in regions underlying the lattice insulative material; and
forming the second sacrificial material to substantially fully extend between adjacent portions of the first electrode material prior to forming the insulative material.

14. The method of claim 7, wherein forming the leaker devices comprises removing portions of the insulative material to form recessed regions therein, the leaker devices individually exhibiting a substantially circular cross-sectional shape in a direction that is transverse to a direction in which the leaker devices extend, with portions of the leaker devices extending into the recessed regions of the insulative material.

15. A method of forming an electronic device, the method comprising:
forming central openings extending through a lattice insulative material;
forming first electrodes adjacent to and partially overlapping the central openings;
forming leaker devices adjacent to the first electrodes; and
forming second electrodes adjacent to the first electrodes to form capacitors.

16. The method of claim 15, wherein forming the leaker devices comprises forming the leaker devices after forming the central openings, portions of the leaker devices within horizontal boundaries of the central openings.

17. The method of claim 15, further comprising:
forming a sacrificial material within the central openings after forming the first electrodes;
removing the sacrificial material after forming the leaker devices; and
forming the second electrodes in locations vacated by the removal of the sacrificial material.

18. The method of claim 15, further comprising forming an insulative material adjacent to the first electrodes prior to forming the leaker devices, the insulative material directly intervening between the first electrodes and the second electrodes, and portions of the leaker devices within recessed regions of the insulative material.

19. The method of claim 15, wherein forming the first electrodes comprises forming two or more openings in communication with and partially overlapping the central openings, the two or more openings individually exhibiting a substantially circular cross-sectional shape in a direction that is transverse to a direction in which the two or more openings extend.

20. The method of claim 15. further comprising forming a sacrificial insulative material directly adjacent to and substantially surrounding the first electrodes prior to forming the leaker devices.
